(19) United States
(12) Patent Application Publication
(10) Pub. No.: US 2012/0160302 A1
(43) Pub. Date: Jun. 28, 2012

(54) TROUGH SHAPED FRESNEL REFLECTOR SOLAR CONCENTRATOR

(76) Inventor: Jeffrey Michael Citron, Tucson, AZ (US)

(21) Appl. No.: 13/337,206

(22) Filed: Dec. 26, 2011

Related U.S. Application Data
(60) Provisional application No. 61/427,433, filed on Dec. 27, 2010.

(51) Int. Cl. H01L 31/058; F24J 2/04; F24J 2/10

(52) U.S. Cl. 136/248; 126/692; 126/634

(57) ABSTRACT

The present invention is a Solar Concentrator composed of a generally V shaped trough of reflective Fresnel steps. Said Fresnel reflective steps concentrate the sunlight entering the mouth of the V shaped trough and parallel to its' central axis into a central focal area. By disposing a solar energy receiving element at the central focal area of sunlight concentration a preferred embodiment as a concentrating solar energy collector is realized. Various types of solar energy receiving structures are shown that serve to convert the concentrated sunlight into other forms of useful energy to realize the preferred embodiment as a concentrating solar energy collector.

This application is based on and claims the priority of this inventor's Provisional Patent Application No. 61/427,433, Filed Dec. 27, 2010.

### BACKGROUND OF THE INVENTION

The present invention is in the field of solar concentrators. More particularly the present invention is shown in the configuration of a solar collector whose purpose is to concentrate solar energy and convert it into other useful forms of energy, although this is not intended to limit its' use to that purpose.

Prior art trough shaped concentrators have either been of the curved, simple or compound parabolic shape, or flat sided V shaped troughs such as the present inventors' prior patent. Both these types of collectors have either cost or physical problems which are eliminated or improved upon by the present invention.

Parabolic reflectors are complex shapes which are expensive to manufacture and require special and expensive support structures to maintain their shape in the outdoor environment of a solar collector. Because of their shape they also require complex and expensive tracking mechanisms. Compound parabolic concentrators have a very tall profile which presents a problem in terms of wind loading in the outdoor environment of a solar collector.

Flat sided V shaped troughs suffer from 2 problems. 1. As their concentration ratio increases they require multiple reflections of some of the suns' rays before those rays reach the receiving element resulting in reduced efficiency. This is due to the fact that reflection of the suns light is not 100% for any reflective surface and therefore each reflection loses some light energy to the reflective surface. Thus multiple reflections of any solar ray may accumulate significant losses before that ray reaches the receiver. 2. In addition, as their concentration ratio increases they must be built narrower and taller, resulting in very tall structures in high concentration ratios, effectively limiting their practical application to relatively low concentration ratios.

### SUMMARY OF THE INVENTION

The present invention is a solar energy concentrator. More particularly it is shown in the preferred embodiment of a solar energy collector. As a solar energy collector it encompasses the solar energy concentrator of the present invention and a receiver element for receiving the concentrated solar energy and converting it to another form of energy. The present invention is comprised of a solar concentrator made of multiple flat parallel linear reflective surfaces in the general shape of a linear trough that reflect and concentrate the solar energy at a linear area located within the boundaries and parallel to the trough structure. More particularly the flat linear reflective surfaces collectively, effectively comprise a Fresnel reflector concentrating the solar energy along the width of line focal point of the Fresnel reflector. The Fresnel reflector of the present invention effectively forms steps along the generally V shaped trough structure of the present concentrator. In one preferred embodiment by putting a solar energy receiving element at the line focal area of the trough shaped Fresnel reflector a solar energy collector is created. This combination of a generally trough shaped concentrator having an underlying V shaped structure with fixed Fresnel reflectors whose axis of concentration is within the bounds of the trough shaped concentrator itself is the new and unique combination of the present invention.

One advantage of the present invention compared to curved trough concentrators is that its' flat linear structure is easily amenable to inexpensive manufacture by being stamped from metallic materials of various gauges. Also it can easily be installed in a protective housing to shield it from environmental factors such as wind loading and hail. If such a housing is provided with a glazing the resulting collector will have thermal insulation properties when built as a thermal collector, properties that most parabolic concentrators lack. In such a configuration commonly available and less expensive tracking mechanisms may be used compared to those required with parabolic troughs.

Compared to flat sided V shaped troughs the present concentrator will have an advantage in efficiency because no solar ray is subject to more than 2 reflections before reaching the receiver and most rays are only subject to one reflection. Flat sided V shaped troughs of higher concentration ratios require multiple reflections of some rays causing loses to the reflector and subsequent lower efficiency. Another advantage of the present invention compared to flat sided V trough concentrators and compound parabolic concentrators in higher concentration ratios, is that the present invention is amenable to being made with wide underlying trough angles thus allowing for a concentrator of relatively high concentration ratio that is not excessively tall.

Further aspects of the invention will become apparent from consideration of the drawings and the ensuing description of preferred embodiments of the invention. A person skilled in the art will realize that other embodiments of the invention are possible and that the details of the invention can be modified in a number of respects, all without departing from the inventive concept. Thus, the following drawings and description are to be regarded as illustrative in nature and not restrictive.

### BRIEF DESCRIPTION OF THE DRAWINGS

FIG. 1a, b and c are crossectional drawings illustrating the theoretical concept of the present invention and showing it in different concentration ratios.

FIG. 2 shows a crossection of the present invention with an alternate solar energy receiving element.

FIG. 3 shows an alternate embodiment with the solar energy receiving element in a different position inside the trough which is the present invention.

FIGS. 4a, b and c show alternate embodiments of the solar energy receiving element.

FIG. 5 is a perspective view of the present invention.

FIG. 6 is a crossectional representation of one possible tracking mechanism for the present invention.

### DETAILED DESCRIPTION OF THE INVENTION

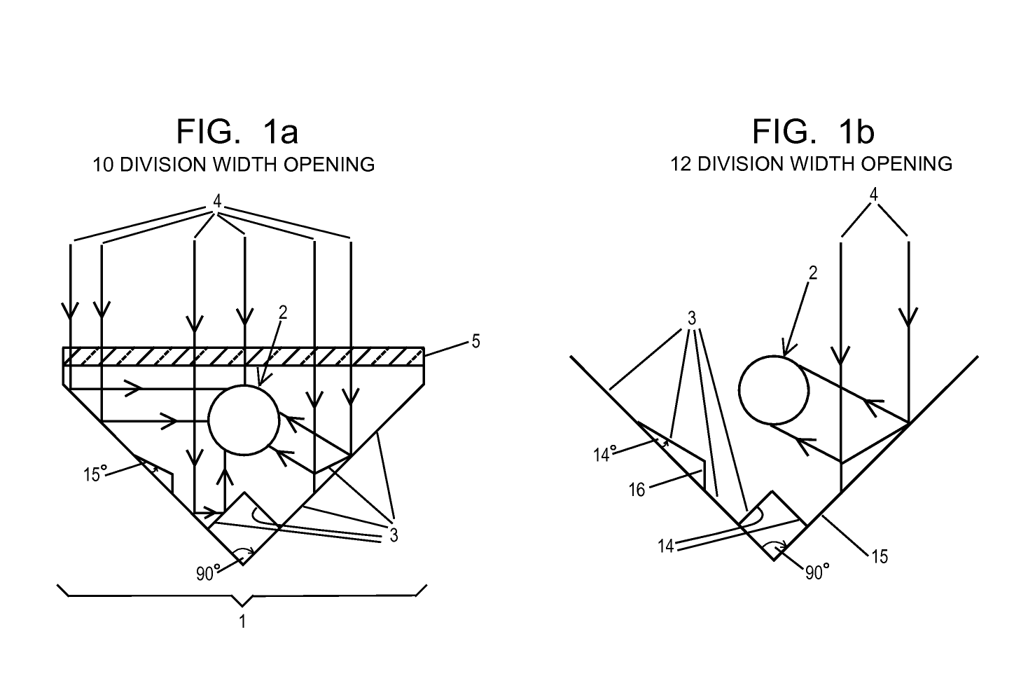

FIGS. 1a, b and c are crossectional representations of the basic concept of the present invention designed to illustrate the theory and operation of the invention.

Referring in detail to FIG. 1a the bracket 1 encompasses the structural elements of the trough shaped Fresnel reflector concentrator of the present invention. It shows the basic V shape of the underlying trough design with the Fresnel steps 3 which have highly reflective surfaces on their inner surfaces facing the inside of the trough. These Fresnel reflector steps 3 reflect all the light entering the mouth or upper opening of the trough structure and parallel to its' central axis onto a smaller area within the structure which is the focal area of the Fresnel reflector thus concentrating the light into that area. This unique shape and structure is the substance of the present invention.

By putting a solar energy receiving element 2 in the focal area along the length of the trough one preferred embodiment of the present invention, a solar collector, is achieved. The solar energy receiving element is a structural element that is designed to receive and absorb solar energy and convert it to another type of energy. In FIG. 1a the solar energy receiving element 2 is a pipe or tube having a dark or black surface through which a fluid such as water or oil is circulated. The black surface of the pipe absorbs the solar energy and converts it to heat which is then transferred to the fluid circulating thru the pipe. FIG. 1a shows the path of the light rays 4, shown with vector arrows, that enter the mouth of the concentrator and how they are reflected off the Fresnel steps 3 onto the receiver 2. Some of these light rays strike the receiver 2 directly from above. Further consideration of FIG 1a shows that the angle of inclination and the width of each reflective Fresnel step must be constructed such that all the light striking it is reflected onto the receiver. It is obvious from an examination of FIG. 1 that only direct solar radiation that is parallel to the troughs central axis is reflected onto the receiver and thus this concentrator like most other trough solar concentrators must track the suns' image across the sky in at least one direction, either in elevation, North/South, or azimuth, East/West. FIG. 1a shows a concentrator with a mouth or opening with a width of 10 divisions that reflects all the direct solar energy entering it, parallel to its' central axis, onto a receiving tube of 2 divisions in diameter thus achieving a concentration ratio of 5 to 1, 5:1.

FIG. 1a shows a glazing 5 covering the mouth of the trough structure thus enhancing the properties of one preferred embodiment of the present invention as a solar thermal collector designed to convert solar energy into heat in a fluid. The glazing 5 is a structural element that will increase the efficiency of energy conversion by providing thermal insulation retarding the convective loss of heat from the hot receiving element and by trapping the loss of energy by infrared emission from the hot receiver. The glazing 5 may be made of glass or a transparent plastic material.

FIG. 1b shows the present invention in its' preferred embodiment as a solar collector with a concentration ratio of 6:1, with an opening width of 12 divisions and a receiver width of 2 divisions. In addition FIG. 1b shows the collector without the glazing. If an evacuated tube solar receiver is used as the receiver 2 in this invention no glazing would be necessary.

Alternatively, in this embodiment the receiver 2 can consist of flexible solar cells wrapped in the shape of a tube, thus creating a concentrating photovoltaic solar collector designed to convert the solar energy into electricity. In addition, the tubular shaped solar cells may be wrapped around and thermally bonded to a pipe in which a fluid is circulated to cool the solar cells, as they are subject to degradation and reduction of conversion efficiency if they heat up much in the concentrated sunlight.

Also one should note in FIG. 1b the 90 degree reflective peak 14 that in conjunction with its' horizontally opposite reflective section of the trough 15 of complementary angle serves to reflect light to the underside of the receiver. It is here to be noted that this particular embodiment with this structures is allowed as a consequence of the underlying 90 degree angle of the trough shaped Fresnel reflector shown in this drawing and embodiment. It is also to be here noted that the particular underlying angle of 90 degrees of the trough shaped Fresnel reflector shown in FIG. 1b and other drawings here, is not a necessary angle for operation of the present invention. In fact, the underlying angle of the trough shaped Fresnel reflector of this invention may be chosen to be any angle up to 90 degrees. Graphical analysis has shown this to be the maximum underlying trough angle for the present invention. It is only necessary that the steps of the Fresnel reflector mounted on the underlying trough shaped structure be so constructed that their angle of inclination and their width reflect all light entering the trough mouth to the desired focal area of the concentrator of the present invention. In the event that the present invention is made with an underlying trough angle other than 90 degrees than the reflecting surfaces of 14 & 15 shown in FIG. 1b must be constructed of other complementary angles that reflect the light onto the receiver or they may be replaced with a single Fresnel reflecting step at the position of reflecting surface 15 that is properly inclined and of the correct width to reflect the light falling on it to the focal area of the concentrator where the receiver is located.

Examination of the structure 16 in FIG. 1b will show that it is a support structure that needs no reflective surface as its' orientation is parallel to the incoming light. The purpose of structure 16, as shown, is to support the Fresnel reflective step above it. Variations of the support function represented by structure 16 are possible.

FIG. 1c shows the present invention in its' preferred embodiment as a solar collector with a concentration ratio of 10:1, with an opening width of 20 divisions and a receiver width of 2 divisions. The bracketed section 17 of the Fresnel reflector shows that the steps of the Fresnel reflector of the present invention need not have underlying V shaped trough walls but may, in manufacture, be formed from material of sufficient gauge to support its' shape. However, considerations of physical strength and stability in an outdoor environment as well as maintaining optical concentration on the focal area during thermal fluctuations of the structure may make the embodiment with underlying V walls below the Fresnel steps preferable.

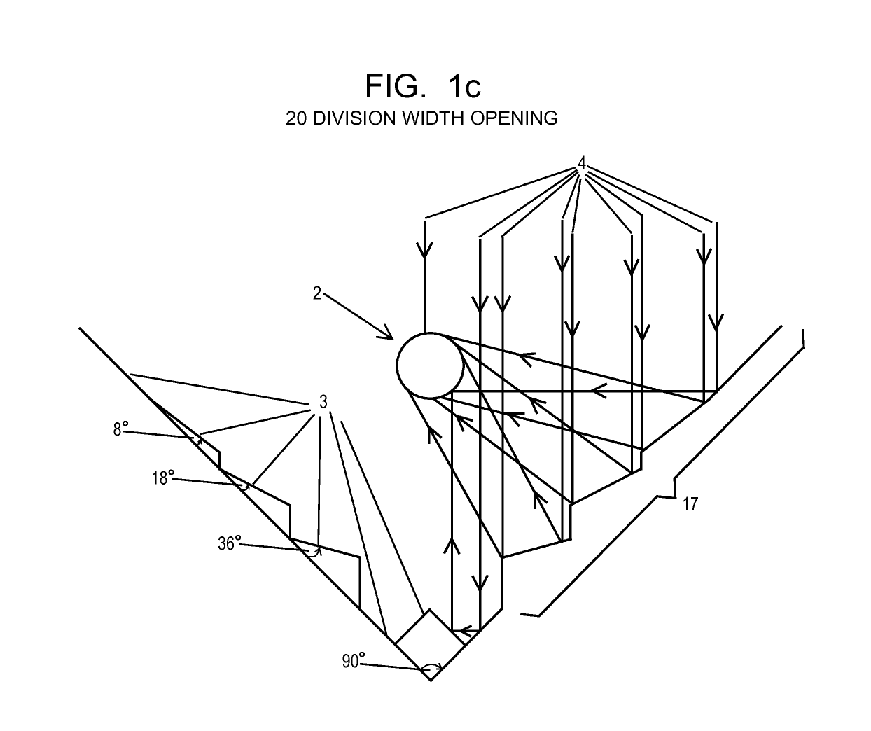

FIG. 2 shows the present invention in its' preferred embodiment as a solar collector with a 10:1 concentration ratio, with an opening of 20 divisions but having a receiver 2 with the cross section of an equilateral triangle each side of which is 2 divisions in length. This receiver 2 may be a triangular shaped tube or pipe with a black outer surface that carries a circulating fluid to be heated or it may be a triangular shaped tube that has photovoltaic solar cells 6 attached to the two underside surfaces or to all three of its' outer surfaces. If configured with solar cells on the surfaces of the triangular receiver, the concentration ratio of sunlight on each of the surfaces facing the Fresnel reflector is 9.5:1 and the sunlight falling on the upper surface is 1:1, 1 sun. In such a configuration the electrical output from the upper surface could be used to power the tracking sensor and mechanism while the output from the lower concentrated light surfaces would be the main power output from the collector.

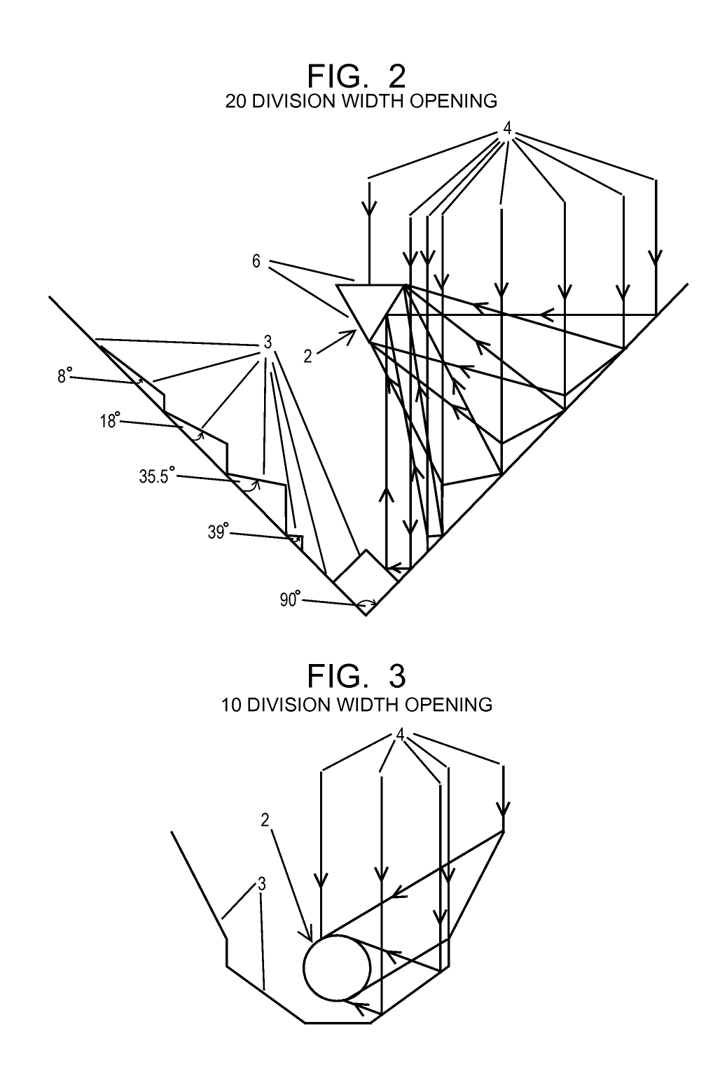

FIG. 3 shows the present invention in its' preferred embodiment as a solar collector with the receiver 2 located not at the top in the center of the mouth opening of the Fresnel trough but with the receiver located in the center near the bottom of the trough shaped Fresnel reflector, illustrating that the receiver 2 need not be only at the top of the trough and, indeed, may be placed at any central position within the generally trough shaped Fresnel reflector structure.

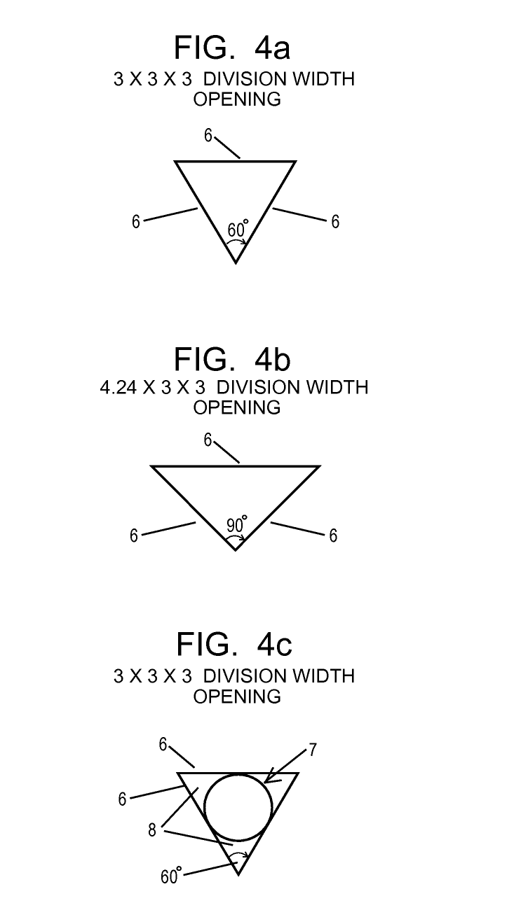

FIGS. 4a, b and c show crossectional drawings of three different possible triangular receiver configurations. The triangular receiver shape is particularly suited to be a receiver in the present invention. The triangular receiver tubes shown in FIGS. 4a, b and c may have a heat collecting fluid circulated thru them or they may have photovoltaic solar cells attached to their outer surfaces 6. It is to be noted here that in the event solar cells are attached to the triangular receiver tubes a cooling liquid or air may be circulated thru them to cool the cells.

FIG. 4a shows a receiver tube whose cross section is an equilateral triangle.

FIG. 4b shows a receiver tube whose cross section is a right triangle. This right triangle receiver tube is especially suited to match the 90 degree angle of the underlying V trough Fresnel reflector structure of the embodiments shown in this document. However, it is again to be mentioned here that the present invention is not limited to the having an underlying V trough angle of 90 degrees and that, indeed, the present invention can be made with any underlying V angle up to 90 degrees.

FIG. 4c shows a receiver tube whose cross section is an equilateral triangle and on whose sides 6 are mounted solar cells. Inside and concentric with the triangular tube is a round tube 7. The round tube 7 is thermally bonded to the triangular tube by a heat transfer material 8 so that a cooling fluid can be circulated thru the round tube 7 to keep the solar cells from overheating.

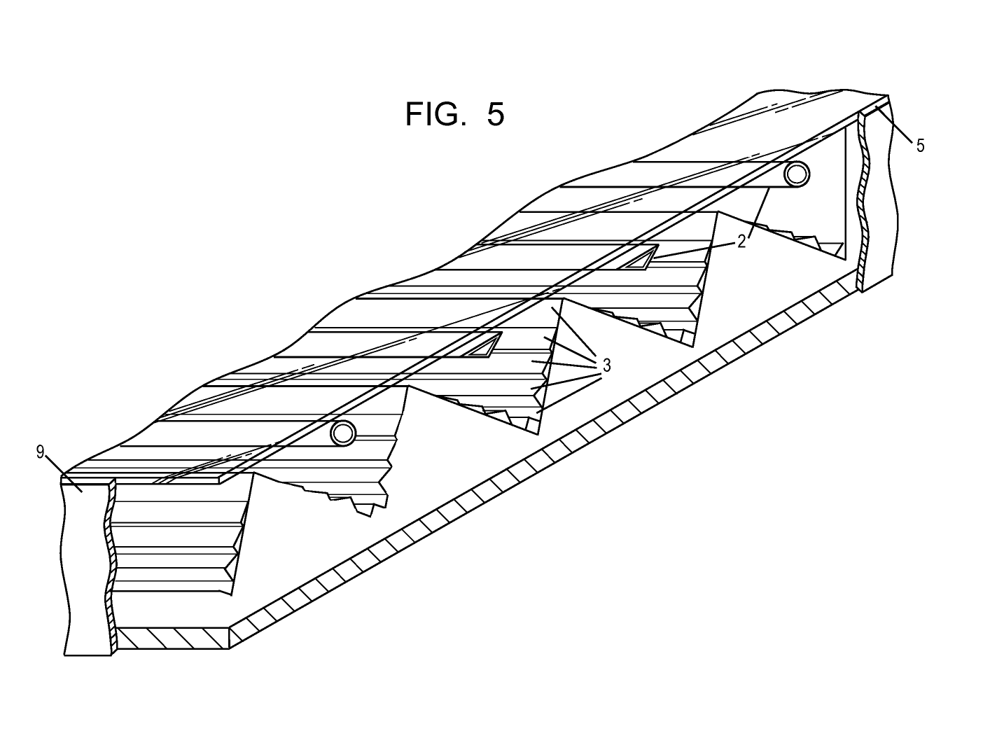

FIG. 5 shows a perspective view of the present invention in its' preferred embodiment as a concentrating solar collector showing both round and triangular tube receivers 2 and showing the reflective steps 3 of the Fresnel reflector. This preferred embodiment is shown in a housing 9 with a glazing 5 covering it.

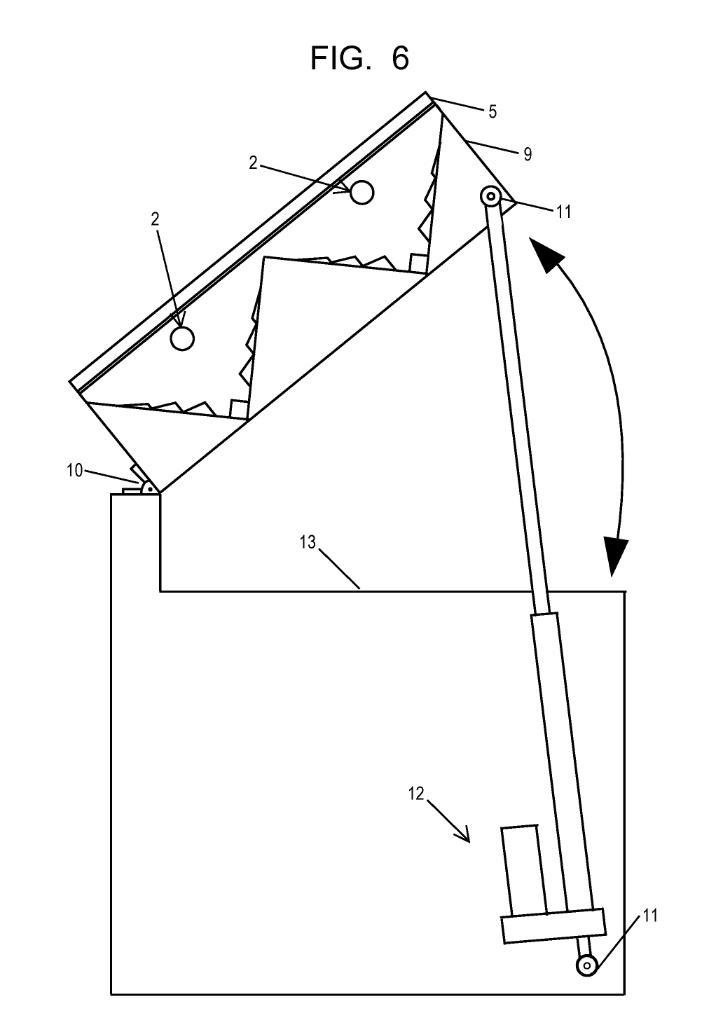

FIG. 6 Shows a simple and inexpensive tracking mechanism that may be used with the present invention in its' preferred embodiment as a solar collector. The tracking mechanism consists of a hinge 10 to which the collector housing 9 is mounted and on which it pivots allowing the collector to track the suns motion across the sky in the vertical, North/South, direction. The hinge 10 is also mounted to a base 13 allowing for the needed angle of rotation for the desired hours of solar energy collection. The rotation of the collector is accomplished by a linear actuator 12 which extends and retracts to pivot the collector on the hinge 10. Pivots 11 where the linear actuator attaches to the collector housing 9 and the base 13 allow for the pivoting motion of the collector and the angular motion of the linear actuator that is required to accomplish the tracking of the collector.

The linear actuator in this tracking mechanism must be controlled by a solar aiming device, not here shown, that tracks the vertical motion of the sun across the sky and provides a signal to the linear actuator telling it in which direction to move the collector & how far, thus keeping the axis of the Fresnel concentrator of the present invention pointed at the sun. Solar aiming devices of this type are readily available off-the-shelf devices.

The tracking mechanism herein described is presented for illustrative purposes only and is not the subject of this invention. Other tracking mechanisms commonly known to the state of the art may be used with the present invention.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

I claim:

1. A solar concentrator comprised of a plurality of flat parallel linear reflective surfaces in the general shape of a linear trough with an underlying V shape. Said reflective surfaces angled to create a Fresnel reflector that collectively reflects and concentrates incoming solar radiation that is parallel to the central axis of said trough to a central focal area that is parallel to the linear axis of said trough and within its' boundaries.

2. A solar energy collector comprised of a plurality of flat parallel linear reflective surfaces in the general shape of a linear trough with an underlying V shape. Said reflective surfaces angled to create a Fresnel reflector that collectively reflects and concentrates incoming solar radiation that is parallel to the central axis of said trough onto a central receiving member that is parallel to the linear axis of said trough and within its' boundaries.

3. The solar energy collector of claim 2 wherein the central receiving member is a tube of crossection designed to receive and absorb all the direct and reflected concentrated solar energy entering the collector and convert it to heat within a fluid passing through said tube.

4. The Solar energy collector of claim 2 wherein the central receiving member is a structure of crossection designed to support photovoltaic cells to receive and convert the solar energy entering the collector into electrical energy.
